(19) United States
(12) Patent Application Publication
(10) Pub. No.: US 2009/0127643 A1
(43) Pub. Date: May 21, 2009

(54) PHOTODIODE OF AN IMAGE SENSOR AND FABRICATING METHOD THEREOF

(76) Inventors: Huo-Tieh Lu, Taipei City (TW); Chin-Sheng Yang, Hsin-Chu City (TW); Pei-Lin Kuo, Taichung City (TW)

Correspondence Address: NORTH AMERICA INTELLECTUAL PROPERTY CORPORATION, P.O. BOX 506, MERRIFIELD, VA, 22116, US

(21) Appl. No.: 11/942,697

(22) Filed: Nov. 19, 2007

(51) Int. Cl. H01L 31/0232; H01L 31/18

(52) U.S. Cl. 257/432; 438/72; 257/E31.128

(57) ABSTRACT

A method for fabricating a photodiode of an image sensor includes providing a substrate having a first conductive type and photo sensing regions, respectively forming photodiodes in the photo sensing region, and performing an ion implantation to form an implanted reflective layer having a second conductive type under the plurality of photodiodes for reflecting light and creating depletion regions in the substrate.

### BACKGROUND OF THE INVENTION

1. Field of the Invention

The invention relates to a photodiode of an image sensor and a fabricating method thereof, and more particularly, to a photodiode having improved sensitivity and the fabricating method thereof.

2. Description of the Prior Art

Complementary metal-oxide-semiconductor (CMOS) image sensor, being one of a common solid-state image sensors, has been gradually replacing the charge-coupled devices (CCDs) due to its advantages such as higher quantum efficiency, lower read-out noise, lower operating voltage, lower power consumption, and ability for random access. Furthermore, the CMOS image sensors are currently capable of integration with the semiconductor fabrication process. Based on those benefits, the application of the CMOS image sensors has increased significantly.

Please refer to FIGS. 1-2, FIG. 1 is a schematic drawing illustrating a layout of a conventional CMOS four-transistor (4T) pixel cell and FIG. 2 is a cross-sectional view of a photodiode of the image sensor shown in FIG. 1 taken along a line A-A′. As shown in FIG. 1, a pixel cell 10 includes a substrate such as a p-type substrate 12 (shown in FIG. 2). The pixel cell 10 also comprises a transfer transistor 20 and a photo sensing area 16 in which a photodiode 30 is located (shown in FIG. 2). The photodiode 30 comprises a p-well 32 and an N-type heavily doped region 34 formed in the substrate 12. Therefore, a depletion region 36 used for generating charge carriers is formed along the PN junction between the N-type heavily doped region 34 and the p-well 32. The photodiode 30 converts the photons to charge carriers, which are transferred to a floating diffusion region 18 through the transfer transistor 20. The floating diffusion region 18 is connected to a source follower transistor 22, which provides an output signal to a row select access transistor 24 for selectively gating the output signal to a terminal 26. The pixel cell 10 also includes a reset transistor 28 for resetting the floating diffusion region 18. And a shallow trench isolation (STI) 14 electrically isolating the pixel cell 10 from other devices is formed in the substrate 12.

When incident light strikes the photodiode 30, as mentioned above, charge carriers are generated in the depletion region 36 and represent signals. Please refer to FIG. 2 again, light having wavelengths shorter than 650 nanometers (nm) is likely to be absorbed closer to the surface of the photodiode 30; while light having longer wavelengths such as 650-750 nm or longer is likely to be absorbed deeper in the substrate 12 and beyond the depletion region 36, even beyond the p-well 32. Therefore, a substantial amount of incident light are not absorbed in the photodiode 30 and thus quantum efficiency of the photodiode 30 is reduced.

To capture light absorbed deep inside the substrate 12, the depletion region 36 can be made deeper. However, charge carriers from one pixel cell are prone to travel to adjacent pixel cells with such a deeper depletion region 36, thus undesirable cross talk is increased. Therefore, a photodiode having improved quantum efficiency without increasing cross talk is in need.

### SUMMARY OF THE INVENTION

It is therefore a primary objective of the claimed invention to provide a photodiode having improved sensitivity without increasing cross talk, and a fabricating method thereof.

According to the claimed invention, a method for fabricating a photodiode of an image sensor is provided. The method includes providing a substrate having a first conductive type and a plurality of photo sensing regions; forming a plurality of photodiodes in the photo sensing region, respectively; and performing an ion implantation to form an implanted reflective layer having a second conductive type under the plurality of photodiodes in the substrate for reflecting light and creating depletion regions.

According to the claimed invention, an image sensor is provided. The image sensor comprises a substrate of a first conductive type having a photo sensing region defined thereon, at least a photodiode formed in the photo sensing region of the substrate, and an implanted reflective layer of a second conductive type formed under the photodiode in the substrate for reflecting light and creating depletion regions.

According to the present invention, the implanted reflective layer formed in the substrate provides at least two benefits: firstly, the implanted reflective layer reflects light passing through the depletion region back to the photodiode. Secondly, the implanted reflective layer having a different conductive type from the substrate is able to create more depletion regions between the photodiode and the implanted reflective layer itself; therefore, more charge carriers can be generated. Accordingly, the photodiode provided by the present invention has improved sensibility.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic drawing of a layout of a conventional CMOS image sensor.

FIG. 2 is a cross-sectional view of a photodiode of the conventional image sensor shown in FIG. 1 taken along a line A-A′.

FIGS. 3-6 are schematic drawings illustrating a method of fabricating a photodiode of an image sensor according to a first preferred embodiment of the invention.

FIGS. 7-8 are schematic drawings illustrating a method of fabricating a photodiode of an image sensor according to a second preferred embodiment of the invention.

### DETAILED DESCRIPTION

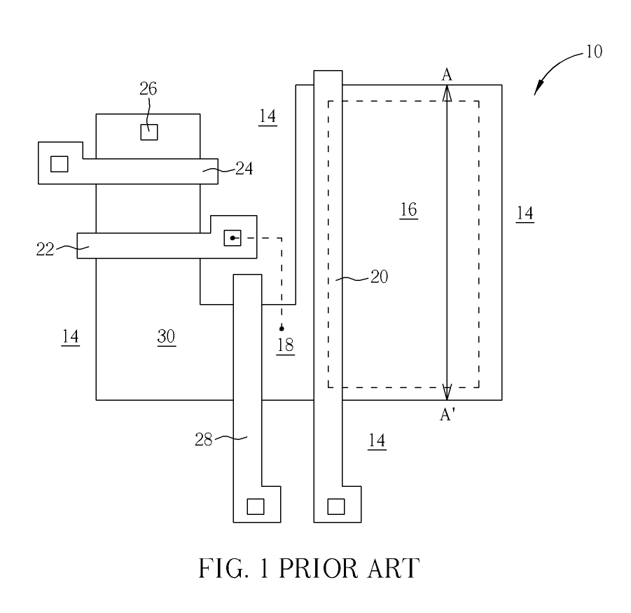

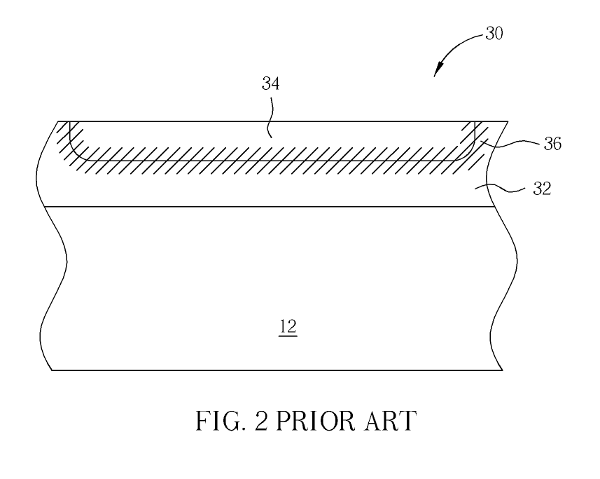

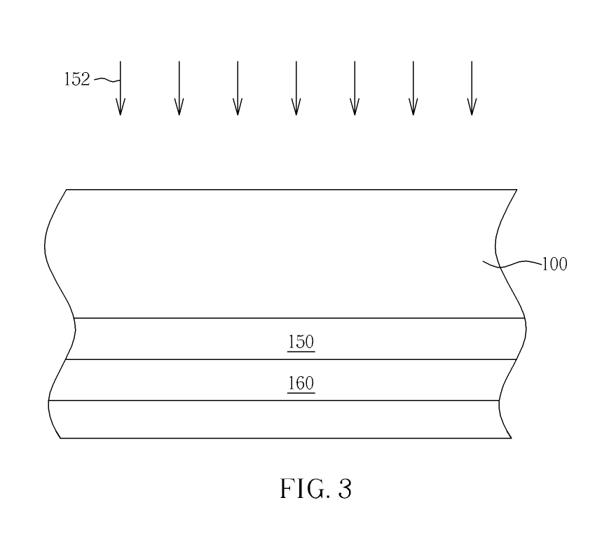

Please refer to FIGS. 3-6, which are schematic drawings illustrating a method of fabricating a photodiode of an image sensor taken along a line A-A′ of FIG. 1 according to a first preferred embodiment of the invention. First, a substrate 100 having a first conductive type, such as p type, is provided. Then a plurality of shallow trench isolations (STIs) (not shown) is formed in the substrate 100 for defining and isolating a plurality of active regions (not shown). The substrate 100 also includes a plurality of photo sensing region 16 (as shown in FIG. 1) defined in the active regions, respectively.

Please still refer to FIG. 3. Then, an ion implantation 152 is performed to form an implanted reflective layer 150 having a second conductive type, such as n type, for reflecting light and creating more depletion regions deeper in the p-type substrate 100. The implanted reflective layer 150 has a refraction index lesser than a refraction index of the substrate 100. It is noteworthy that the implanted reflective layer 150 is used to reflect longer-wavelength light that passes through a photodiode (not shown) without being absorbed back to the photodiode; therefore, the implanted reflective layer 150 is formed in the substrate 100 with a depth of 4-7 μm under a surface of the substrate 100. In the first preferred embodiment, the ion implantation 152 is performed to a front side of the substrate 100 with a dosage of about 10¹⁴ atoms/cm³ and an energy of about 4 KeV.

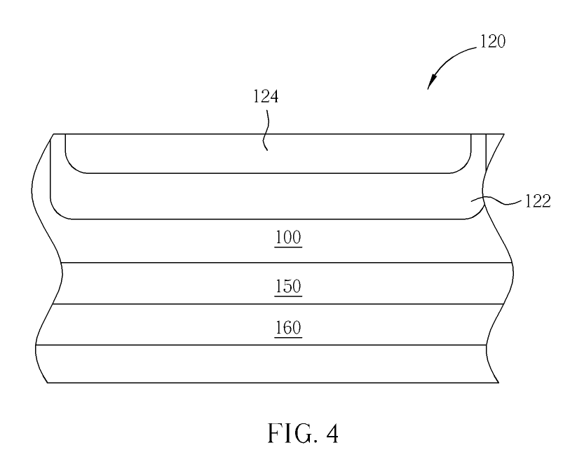

Please refer to FIG. 4. Next, a step for forming a photodiode 120 in the photo sensing region 16 is performed. This step comprises forming a first implanted region 122 in the photo sensing region 16 and forming a second implanted region 124 on the first implanted region 122, sequentially. As shown in FIG. 4, the first implanted region 122 is a p-type lightly doped region, while the second implanted region 124 is an n-type heavily doped region; thus, a pinned photodiode 120 is obtained.

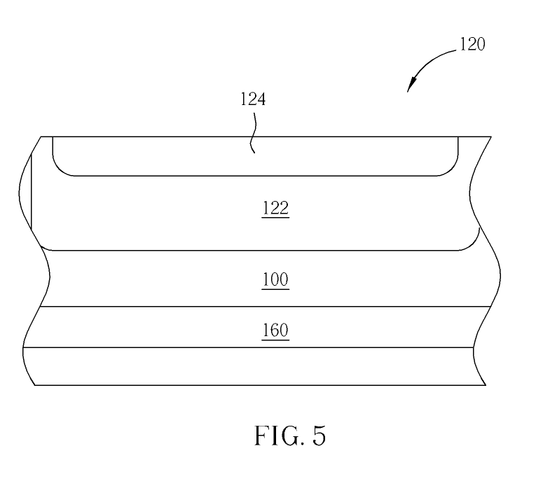

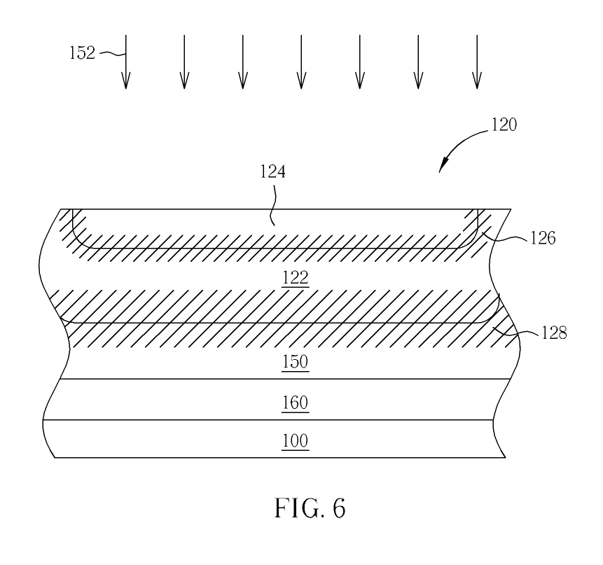

In the first preferred embodiment, the ion implantation 152 is performed before forming the pinned photodiode 120. However, it is appreciated that the ion implantation 152 also can be performed after forming the pinned photodiode 120, as shown in FIGS. 5-6. Moreover, the ion implantation 152 also can be performed after the forming of transistors (not shown); the ion implantation 152 can even be performed to a rear side of the substrate 100 after a wafer thinning process is performed. In addition, a dielectric layer having a refraction index smaller than that of the substrate 100, such as a silicon oxide layer 160, is selectively formed under the implanted reflective layer 150 as shown in FIGS. 3-6. Otherwise, a silicon-on-insulator (SOI) substrate can be used in lieu of the silicon oxide layer 160 in the first preferred embodiment.

According to the first preferred embodiment, an image sensor is provided. The image sensor comprises the substrate 100 of a first conductive type such as p type with a photo sensing region 16 in which the photodiode 120 is located. The photodiode 120 also comprises at least a first implanted region 122 and a second implanted region 124 formed in the photo sensing region 16. As mentioned above, the first implanted region 122 is a p-type lightly doped region while the second implanted region 124 is an n-type heavily doped region. The photodiode 120 further comprises an implanted reflective layer 150 of a second conductive type, such as n type, formed in the substrate 100 with a depth of 4-7 μm under a surface of the substrate 100. In addition, a dielectric layer having a refraction index lesser than that of the substrate 100, such as the silicon oxide layer 160, is selectively formed under the implanted reflective layer 150 in the substrate 100. A SOI substrate can be used in lieu of the silicon oxide layer 160 in the first preferred embodiment.

Please refer to FIG. 6 again. The implanted reflective layer 150 having a refraction index lesser than that of the substrate 100 is able to reflect light that passes through the photodiode 120 without being absorbed back to the photodiode 120; therefore, more charge carriers can be generated. Since the implanted reflective layer 150 formed in substrate 100 is deeper than the photodiode 120, it is more likely to reflect light having longer wavelengths which is prone to be absorbed in the deeper substrate 100. Furthermore, it is well-known that there is a depletion region 126 for generating charge carriers formed along the PN junction between the first implanted region 122 and the second implanted region 124. And according to the first preferred embodiment, the implanted reflective layer 150 creates more depletion regions 128 between the photodiode 120 and the implanted reflective layer 150 itself. Therefore, light without being reflected back to the photodiode 120 still can be absorbed; and more charge carriers can be generated in the depletion region 128, particularly for light having longer wavelengths. Consequently, the photodiode 120 provided by the present invention is able to achieve an improved sensitivity without increasing the undesirable cross talk.

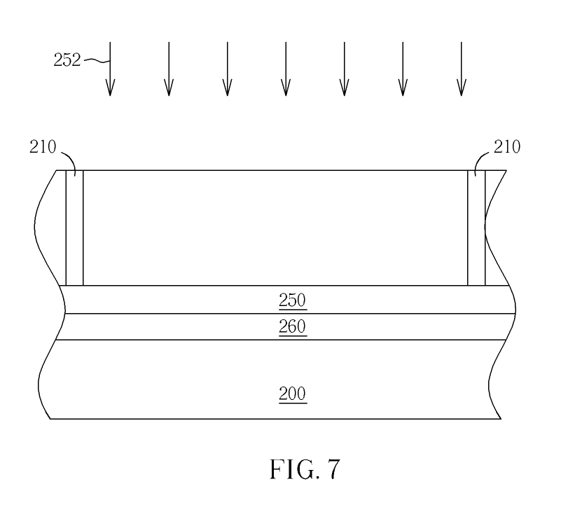

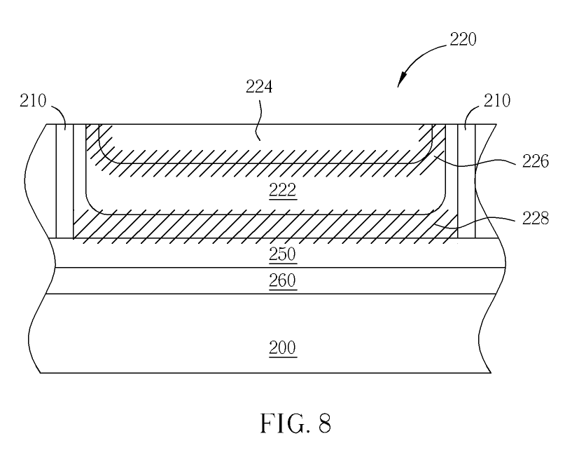

Please refer to FIGS. 7-8, which are schematic drawings illustrating a method of fabricating a photodiode of an image sensor taken along a line A-A′ of FIG. 1 according to a second preferred embodiment of the invention. First, a substrate 200 having a first conductive type, such as p type, is provided. Then a plurality of shallow trench isolations (STIs) (not shown) is formed in the substrate 200 for defining and isolating a plurality of active regions (not shown). The substrate 200 also includes a plurality of photo sensing region 16 (as shown in FIG. 1) defined in the active regions, respectively. It is noteworthy that a plurality of voids 210 is formed in the substrate 100 simultaneously when forming a plurality of shallow trenches used for constructing the STIs in the second preferred embodiment. The voids 210 are formed surrounding the photo sensing region 16 in which a photodiode is formed by the following processes. Furthermore, the voids 210 can be filled or coated with metal or materials having a refraction index lesser than that of the substrate 200; therefore, it is able to reflect light. When the voids 210 are formed without having any conductive material filled in, the voids 210 even can replace the STI surrounding the photodiode for providing electrical isolation, besides of the reflective function.

Please still refer to FIG. 7. Then, an ion implantation 252 is performed to form an implanted reflective layer 250 having a second conductive type, such as n type, for reflecting light and creating more depletion regions deeper in the p-type substrate 200. The implanted reflective layer 250 has a refraction index lesser than that of the substrate 200. It is noteworthy that the implanted reflective layer 250 is used for reflecting longer-wavelength light that passes through a photodiode (not shown) without being absorbed back to the photodiode; therefore, the implanted reflective layer 250 is formed in the substrate 200 with a depth of 4-7 μm under a surface of the substrate 200. In the second preferred embodiment, the ion implantation 252 is performed to a front side of the substrate 200 with a dosage of about 10¹⁴ atoms/cm³ and an energy of about 4 KeV.

Please refer to FIG. 8. Next, a step for forming a photodiode 220 in the photo sensing region 16 is performed. This step comprises forming a first implanted region 222 in the photo sensing region 16 and forming a second implanted region 224 on the first implanted region 222, sequentially. As shown in FIG. 8, the first implanted region 222 is a p-type lightly doped region, while the second implanted region 224 is an n-type heavily doped region; thus a pinned photodiode 220 is obtained.

In the second preferred embodiment, the ion implantation 252 is performed before the pinned photodiode 220 is formed. However, the ion implantation 252 can also be performed after the pinned photodiode 220 is formed. Moreover, the ion implantation 252 can be performed after forming transistors (not shown); the ion implantation 252 can even be performed to a rear side of the substrate 200 after a wafer thinning process is performed. Since such steps are similar with that described in the first preferred embodiment, details are omitted in the interest of brevity. In addition, a dielectric layer having a refraction index lesser than that of the substrate 200, such as a silicon oxide layer 260, is selectively formed under the implanted reflective layer 250 as shown in FIGS. 7-8. Otherwise, a SOI substrate can be used in lieu of the silicon oxide layer 260 in the second preferred embodiment.

According to the second preferred embodiment, an image sensor is provided. The image sensor comprises the substrate 200 of a first conductive type, such as p type, having a photo sensing region 16 in which the photodiode 220 is located. The photodiode 220 also comprises at least a first implanted region 222 and a second implanted region 224 formed in the photo sensing region 204. As mentioned above, the first implanted region 222 is a p-type lightly doped region, while the second implanted region 224 is an n-type heavily doped region. The photodiode 220 further comprises an implanted reflective layer 250 of a second conductive type, such as n type formed in the substrate 200 with a depth of 4-7 μm under the surface of the substrate 200, and a plurality of voids are 210 formed surrounding the photodiode 220 itself. In addition, a dielectric layer having a refraction index lesser than that of the substrate 200, such as the silicon oxide layer 260, is selectively formed under the implanted reflective layer 250 in the substrate 100. A SOI substrate can be used in lieu of the silicon oxide layer 260 in the second preferred embodiment.

As shown in FIG. 8. The implanted reflective layer 250, which is provided by the second preferred embodiment, is able to reflect light that passes through the photodiode 220 without being absorbed back to the photodiode 220; therefore, more charge carriers can be generated. Since the implanted reflective layer 250 formed in substrate 200 is deeper than the photodiode 220 in the substrate 200, it is more beneficial to reflect light having longer wavelengths which is prone to be absorbed in deeper substrate 200. And the voids 210 filled with metal or materials having a refraction index lesser than that of the substrate 200 is able to reflect more light back into the photodiode 220. Furthermore, it is well-known that there is a depletion region 226 formed along the PN junction between the first implanted region 222 and the second implanted region 224. And the implanted reflective layer 250 creates more depletion regions 228 between the photodiode 220 and the implanted layer 250 itself. Therefore, light without being reflected back to the photodiode 220 still can be absorbed; and more charge carriers can be generated, especially for light having longer wavelengths. Consequently, the photodiode 220 provided by the present invention obtains an improved sensitivity without increasing the undesirable cross talk.

According to the present invention, the implanted reflective layer formed in the substrate provides at least two benefits: the implanted reflective layer reflects light that passes through the depletion region formed along a PN junction of the photodiode back to the photodiode. In addition, with supplement from the voids which are either filled with or without metal or materials having a refraction index lesser than that of the substrate, more light is reflected back to the photodiode, thus more charge carriers can be generated in the depletion region of the photodiode. Secondly, the implanted reflective layer having different conductive type from the substrate is able to create more depletion regions between the photodiode and the implanted reflective layer itself. Therefore, more charge carriers can be generated. Accordingly, the photodiode provided by the present invention has improved sensitivity without having increased cross talk.

Those skilled in the art will readily observe that numerous modifications and alterations of the device and method may be made while retaining the teachings of the invention.

What is claimed is:

1. A method for fabricating a photodiode of an image sensor, comprising steps of:
providing a substrate having a first conductive type and a plurality of photo sensing regions;
forming a plurality of photodiodes in the photo sensing region, respectively; and
performing an ion implantation to form an implanted reflective layer having a second conductive type under the plurality of photodiodes in the substrate for reflecting light and creating depletion regions.

2. The method of claim 1, wherein the implanted reflective layer is formed with a depth of 4-7 μm under a surface of the substrate.

3. The method of claim 1, wherein the ion implantation is performed to a front side of the substrate.

4. The method of claim 3, wherein the ion implantation is performed with a dosage of about 10¹⁴ atoms/cm³ and an energy of about 4 KeV.

5. The method of claim 1, wherein the ion implantation is performed before forming the photodiode.

6. The method of claim 1, wherein the ion implantation is performed after forming the photodiode.

7. The method of claim 1, wherein the ion implantation is performed to a rear side of the substrate after a wafer thinning process.

8. The method of claim 1, wherein a refraction index of the implanted reflective layer is lesser than a refraction index of the substrate.

9. The method of claim 1, further comprising forming a plurality of voids surrounding the photodiodes, respectively.

10. The method of claim 9, wherein the voids are filled or coated with metal.

11. The method of claim 9, wherein the voids are filled with materials having a refraction index lesser than a refraction index of the substrate.

12. The method of claim 1, further comprising forming a dielectric layer under the implanted reflective layer.

13. The photodiode of claim 1, wherein the first conductive type is p type and the second conductive type is n type.

14. An image sensor comprising:
a substrate of a first conductive type having a photo sensing region defined thereon;
at least a photodiode formed in the photo sensing region of the substrate; and
an implanted reflective layer of a second conductive type formed under the photodiode in the substrate for reflecting light and creating depletion regions.

15. The photodiode of claim 14, wherein the implanted reflective layer is formed with a depth of 4-7 μm under a surface of the substrate.

16. The photodiode of claim 14, wherein refraction index of the implanted reflective layer is lesser than refraction index of the substrate.

17. The photodiode of claim 14, further comprising a plurality of voids formed surrounding the photodiodes.

18. The photodiode of claim 17, wherein the voids are filled or coated with metal or materials having refraction index lesser than a refraction index of the substrate.

19. The photodiode of claim 14, further comprising a dielectric layer formed under the implanted reflective layer.

20. The photodiode of claim 14, wherein the first conductive type is p type and the second conductive type is n type.
